(19) United States
(12) Patent Application Publication
(10) Pub. No.: US 2012/0132265 A1
(43) Pub. Date: May 31, 2012

(54) PHOTOVOLTAIC DEVICE

(75) Inventor: Tatsuyuki Nishimiya, Tokyo (JP)

(73) Assignee: MITSUBISHI HEAVY INDUSTRIES, LTD., Tokyo (JP)

(21) Appl. No.: 13/266,770

(22) PCT Filed: Aug. 10, 2010
(86) PCT No.: PCT/JP2010/063533

§ 371 Date: Nov. 3, 2011

(30) Foreign Application Priority Data
Sep. 17, 2009 (JP) 2009-215705

(51) Int. Cl. H01L 31/0264; H01L 31/0725; H01L 31/075

(52) U.S. Cl. 136/255; 136/261

(57) ABSTRACT

A photovoltaic device that exhibits superior electric power generation efficiency due to suppression of diffusion of oxygen from a transparent electrode layer into a microcrystalline silicon p-layer. A photovoltaic device (100) comprises a transparent electrode layer (2) and one or more photovoltaic layers (3) stacked on a substrate (1), wherein at least one of the photovoltaic layers (3) comprises a p-type crystalline silicon layer (41), an i-type crystalline silicon layer (42) and an n-type silicon layer (43), and an amorphous silicon layer (7) is disposed between and adjacent to the transparent electrode layer (2) and the p-type crystalline silicon layer (41).

### TECHNICAL FIELD

The present invention relates to a solar cell, and relates particularly to a thin-film solar cell that uses silicon as the electric power generation layer.

### BACKGROUND ART

One known example of a photovoltaic device that receives light and converts the light into electric power is a thin-film solar cell comprising an electric power generation layer (a photovoltaic layer) formed by stacking thin films of silicon-based layers. Thin-film solar cells generally have a structure in which a transparent electrode layer, a silicon-based semiconductor layer (photovoltaic layer) and a back electrode layer are stacked sequentially on a substrate.

The transparent electrode layer is composed of a transparent conductive film comprising a metal oxide such as zinc oxide (ZnO), tin oxide (SnO₂) or indium tin oxide (ITO) as the main component.

The photovoltaic layer is formed from amorphous silicon or crystalline silicon, and has a pin junction formed from a p-type silicon-based semiconductor (p-layer), an i-type silicon-based semiconductor (i-layer) and an n-type silicon-based semiconductor (n-layer). This pin junction functions as the energy conversion unit, converting the light energy from sunlight into electrical energy.

PTL1 discloses a photovoltaic device comprising a crystalline silicon-based photovoltaic layer formed using a low-temperature process that utilizes a plasma-enhanced CVD method.

### CITATION LIST

### Patent Literature

{PTL 1} Japanese Unexamined Patent Application, Publication No. Hei 11-87742 (claim 1, paragraphs [0008] and [0009])

### SUMMARY OF INVENTION

### Technical Problem

In a solar cell that uses microcrystalline silicon, a microcrystalline silicon p-layer is generally stacked on the transparent electrode layer as a photovoltaic layer. As a result, oxygen contained within the transparent electrode layer tends to diffuse and become incorporated within the microcrystalline silicon p-layer. It is said that when oxygen is incorporated in a microcrystalline silicon layer, a donor level associated with the oxygen is formed. For example, in the case of intrinsic microcrystalline silicon, this causes an n-type transition. Because this formation of a donor level has the effect of weakening the p-type conductivity of a microcrystalline silicon p-layer, conventionally, the p-type conductivity has been maintained by increasing the doping concentration beyond the required level. However, with this method, the band gap of the microcrystalline silicon p-layer narrows, and light absorption loss tends to occur, resulting in a reduced short-circuit current. On the other hand, if the dopant content is reduced in order to prevent any reduction in the short-circuit current, then insufficient doping of the microcrystalline silicon p-layer tends to cause a deterioration in the open-circuit voltage and the fill factor. This results in a deterioration in the electric power generation efficiency of the photovoltaic device.

In the silicon-based thin-film photovoltaic device of PTL1, an ultra thin substantially i-type amorphous silicon-based thin film is introduced between the p-layer and the i-layer of the crystalline silicon photovoltaic layer, thereby appropriately suppressing the density of small grain-size crystalline silicon that can cause the generation of crystal nuclei within the crystalline silicon-based photovoltaic layer, and yielding a favorable photovoltaic layer that has minimal crystal grain boundaries and transgranular fractures and is strongly oriented in a single direction. The invention disclosed in PTL1 inserts an amorphous silicon thin-film photovoltaic layer as a base layer for the purpose of improving the crystallinity of a crystalline silicon-containing thin-film photovoltaic layer produced in a low-temperature process. However, with this type of structure, the above-mentioned problems wherein oxygen contained within the transparent conductive film diffuses into the microcrystalline silicon p-layer, causing a reduction in the short-circuit current or a deterioration in the electric power generation efficiency and the fill factor, cannot be addressed.

The present invention has been developed in light of the above circumstances, and has an object of providing a photovoltaic device that has a high electric power generation efficiency while maintaining the p-type conductivity of the crystalline silicon p-layer.

### Solution to Problem

In order to achieve the above object, the present invention provides a photovoltaic device comprising a transparent electrode layer and one or more photovoltaic layers stacked on a substrate, wherein at least one of the photovoltaic layers comprises a p-type crystalline silicon layer, an i-type crystalline silicon layer and an n-type silicon layer, and an amorphous silicon layer is disposed between and adjacent to the transparent electrode layer and the p-type crystalline silicon layer.

In the present invention, by interposing an amorphous silicon layer between and adjacent to the transparent electrode layer and the p-type crystalline silicon layer, oxygen contained within the transparent electrode layer can be prevented from diffusing into the p-type crystalline silicon layer. As a result, a transition of the p-type crystalline silicon layer to n-type conductivity can be suppressed, inhibiting any deterioration in the electric power generation efficiency when the layer is used in a photovoltaic device. In this description, the term “transparent electrode layer” also includes layers formed from a transparent conductive film containing a metal oxide as the main component, such as an intermediate contact layer.

Compared with the case where the crystalline silicon p-layer is deposited on the transparent electrode layer, depositing the crystalline silicon p-layer on an amorphous silicon layer can suppress light loss caused by reduction of the transparent electrode layer, and improves the amount of light absorbed by the crystalline silicon layers that constitute the electric power generation layer, resulting in improved electric power generation efficiency. Accordingly, for an equivalent level of efficiency, the thickness of the crystalline silicon layers can be reduced, enabling productivity to be improved.

In one aspect of the present invention, the photovoltaic device may comprise two or more of the photovoltaic layers, and the transparent electrode layer may be an intermediate contact layer disposed between a pair of the two or more photovoltaic layers, wherein among the pair of photovoltaic layers, the photovoltaic layer positioned on the opposite side of the intermediate contact layer from the substrate comprises a p-type crystalline silicon layer containing mainly crystalline silicon, an i-type crystalline silicon layer and an n-type silicon layer, and an amorphous silicon layer is disposed between and adjacent to the intermediate contact layer and the p-type crystalline silicon layer.

By interposing an amorphous silicon layer between and adjacent to the intermediate contact layer and the p-type crystalline silicon layer, oxygen contained within the intermediate contact layer can be prevented from diffusing into the p-type crystalline silicon layer. As a result, a transition of the p-type crystalline silicon layer to n-type conductivity can be suppressed, inhibiting any deterioration in the electric power generation efficiency when the layer is used in a photovoltaic device.

In another aspect of the present invention, the amorphous silicon layer is preferably a p-type amorphous silicon layer or an i-type amorphous silicon layer. The amorphous silicon layer has the effect of preventing diffusion of oxygen from the transparent electrode layer into the p-type crystalline silicon layer. Because the amorphous silicon layer is disposed in contact with the p-type crystalline silicon layer, a p-type amorphous silicon layer having similar electrical properties to those of the p-type crystalline silicon layer is particularly desirable. If the amorphous silicon layer is an i-type layer, then when a photovoltaic device is produced, impurities (such as the dopant) may diffuse from the p-type crystalline silicon layer stacked on top of the i-type amorphous silicon layer, making identification of the i-type conductivity and p-type conductivity difficult.

In yet another aspect of the present invention, the thickness of the amorphous silicon layer is preferably not less than 1 nm and not more than 30 nm, and is more preferably not less than 5 nm and not more than 20 nm. Because the amorphous silicon layer has a lower conductivity than a crystalline silicon layer, if the thickness of the layer exceeds 30 nm, then the contact resistance increases at the interface between the amorphous silicon layer and the crystalline silicon layer. On the other hand, a thickness of at least 1 nm is necessary to ensure that the oxygen diffusion inhibiting effect is realized satisfactorily.

### Advantageous Effects of Invention

According to the present invention, by inserting an amorphous silicon layer between a transparent electrode layer and a p-type crystalline silicon layer, diffusion of oxygen from the transparent electrode layer into the p-type crystalline silicon layer can be prevented, thereby improving the electric power generation efficiency of the photovoltaic device.

### BRIEF DESCRIPTION OF DRAWINGS

FIG. 1A cross-sectional view showing a schematic illustration of the structure of a photovoltaic device according to an embodiment of the present invention.

FIG. 2 A schematic illustration describing one embodiment for producing a solar cell panel that represents a photovoltaic device according to an embodiment of the present invention.

FIG. 3 A schematic illustration describing one embodiment for producing a solar cell panel that represents a photovoltaic device according to an embodiment of the present invention.

FIG. 4 A schematic illustration describing one embodiment for producing a solar cell panel that represents a photovoltaic device according to an embodiment of the present invention.

FIG. 5 A schematic illustration describing one embodiment for producing a solar cell panel that represents a photovoltaic device according to an embodiment of the present invention.

FIG. 6 A cross-sectional view showing a schematic illustration of the structure of a single crystalline silicon solar cell according to an Example 1.

FIG. 7 A graph illustrating the relationship between the thickness of an amorphous silicon p-layer and the electric power generation efficiency in Example 1.

FIG. 8 A graph illustrating the relationship between the thickness of an amorphous silicon i-layer and the electric power generation efficiency in Example 2.

### DESCRIPTION OF EMBODIMENTS

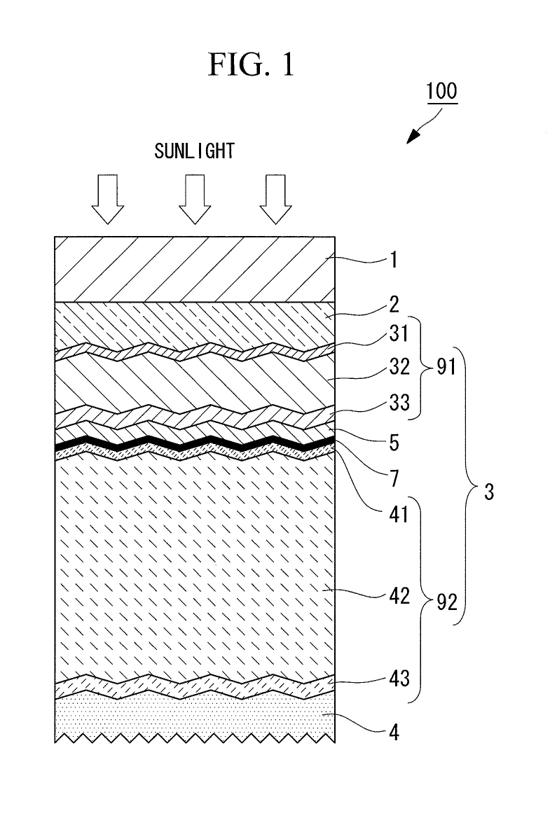

FIG. 1 is a schematic illustration of the structure of a photovoltaic device of the present invention. The photovoltaic device 100 is a tandem silicon-based solar cell, and comprises a substrate 1, a transparent electrode layer 2, a first cell layer (first photovoltaic layer) 91 (amorphous silicon-based) and a second cell layer (second photovoltaic layer) 92 (crystalline silicon-based) that function as a solar cell photovoltaic layer 3, an intermediate contact layer 5, and a back electrode layer 4. Here, the terms “silicon-based” and “silicon series” are generic terms that include silicon (Si), silicon carbide (SiC) and silicon germanium (SiGe). Further, a crystalline silicon series describes a silicon series other than an amorphous silicon series, and includes both microcrystalline silicon series and polycrystalline silicon series.

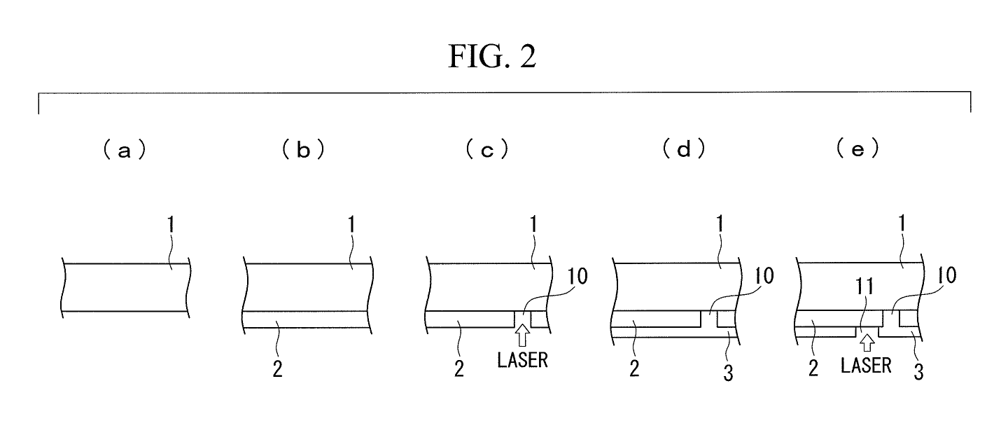

A process for producing a photovoltaic device according to the present embodiment is described below, using the production steps for a solar cell panel as an example. FIG. 2 to FIG. 5 are schematic representations illustrating the process for producing a solar cell panel according to this embodiment.

(1) FIG. 2(a)

A soda float glass substrate with a surface area of at least 1 m² (for example with dimensions of 1.4 m×1.1 m× thickness: 3.5 to 4.5 mm) is used as the substrate 1. The edges of the substrate are preferably subjected to corner chamfering or R-face chamfering to prevent damage caused by thermal stress or impacts or the like.

(2) FIG. 2(b)

A transparent conductive film comprising mainly tin oxide (SnO₂) and having a film thickness of approximately not less than 500 nm and not more than 800 nm is deposited as the transparent electrode layer 2, using a thermal CVD apparatus at a temperature of approximately 500° C. During this deposition, a texture comprising suitable asperity is formed on the surface of the transparent conductive film. In addition to the transparent conductive film, the transparent electrode layer 2 may also include an alkali barrier film (not shown in the figure) formed between the substrate 1 and the transparent conductive film. The alkali barrier film is formed using a thermal CVD apparatus at a temperature of approximately 500° C. to deposit a silicon oxide film (SiO₂) having a film thickness of 50 nm to 150 nm.

The SnO₂ film has low plasma resistance, and under the deposition conditions for the photovoltaic layer, which include a large plasma density using hydrogen, the SnO₂ film tends to undergo reduction. Reduction of the SnO₂ film tends to cause a deterioration in the electric power generation efficiency. Accordingly, a GZO (Ga-doped ZnO) film having a thickness of not less than 100 nm and not more than 450 nm is deposited on the transparent electrode layer 2 as a plasma-resistant protective layer (not shown in the figure), using a sputtering apparatus with a Ga₂O₃-doped ZnO sintered compact as the target. In some cases, the plasma-resistant protective layer may not be provided.

(3) FIG. 2(c)

Subsequently, the substrate 1 is mounted on an X-Y table, and the first harmonic of a YAG laser (1064 nm) is irradiated onto the surface of the transparent conductive film, as shown by the arrow in the figure. The laser power is adjusted to ensure an appropriate process speed, and the transparent conductive film is then moved in a direction perpendicular to the direction of the series connection of the electric power generation cells, thereby causing a relative movement between the substrate 1 and the laser light, and conducting laser etching across a strip having a predetermined width of approximately 6 mm to 15 mm to form a slot 10.

(4) FIG. 2(d)

Using a plasma-enhanced CVD apparatus, a p-layer, an i-layer and an n-layer, each composed of a thin film of amorphous silicon, are deposited as the first cell layer 91. Using SiH₄ gas and H₂ gas as the main raw materials, and under conditions including a reduced pressure atmosphere of not less than 30 Pa and not more than 1,000 Pa and a substrate temperature of approximately 200° C., a first amorphous silicon p-layer 31, a first amorphous silicon i-layer 32 and a first amorphous silicon n-layer 33 are deposited, in that order, on the transparent electrode layer 2, with the p-layer closest to the surface from which incident sunlight enters. The first amorphous silicon p-layer 31 comprises mainly amorphous B-doped silicon, and has a thickness of not less than 10 nm and not more than 30 nm. The first amorphous silicon i-layer 32 has a thickness of not less than 200 nm and not more than 350 nm. The first amorphous silicon n-layer 33 comprises mainly P-doped silicon in which microcrystalline silicon is incorporated within amorphous silicon, and has a thickness of not less than 30 nm and not more than 50 nm. A buffer layer may be provided between the first amorphous silicon p-layer 31 and the first amorphous silicon i-layer 32 in order to improve the interface properties.

An intermediate contact layer 5 that functions as a semi-reflective film for improving the contact properties and achieving electrical current consistency is provided on the first cell layer 91. A GZO (Ga-doped ZnO) film with a film thickness of not less than 20 nm and not more than 100 nm is deposited as the intermediate contact layer 5, using a sputtering apparatus with a Ga-doped ZnO sintered compact as the target.

A p-type second amorphous silicon layer 7 is deposited on the intermediate contact layer 5 using a plasma-enhanced CVD apparatus. SiH₄ gas, H₂ gas and B₂H₆ gas are used as the main raw materials, and the deposition is performed under conditions including a reduced pressure atmosphere of not less than 30 Pa and not more than 1,000 Pa and a substrate temperature of approximately 200° C. The second amorphous silicon p-layer comprises mainly amorphous B-doped silicon, and has a thickness of not less than 1 nm and not more than 30 nm. If the thickness is restricted to not less than 5 nm and not more than 20 nm, then the electric power generation efficiency is further improved when a solar cell module is produced.

Amorphous SiC or amorphous SiO may also be used as the amorphous silicon.

The p-type second amorphous silicon layer 7 may be an i-type second amorphous silicon layer. In this case, the second amorphous silicon i-layer is deposited using a plasma-enhanced CVD apparatus. SiH₄ gas and H₂ gas are used as the main raw materials, and the deposition is performed under conditions including a reduced pressure atmosphere of not less than 30 Pa and not more than 1,000 Pa and a substrate temperature of approximately 200° C. The second amorphous silicon i-layer comprises mainly amorphous silicon, and has a thickness of not less than 1 nm and not more than 20 nm. If the thickness is restricted to not less than 5 nm and not more than 10 nm, then the electric power generation efficiency is further improved when a solar cell module is produced.

Amorphous SiC or amorphous SiO may also be used as the amorphous silicon.

Using a plasma-enhanced CVD apparatus, a p-layer, an i-layer and an n-layer, each composed of a thin film of crystalline silicon, are deposited as the second cell layer 92. Using SiH₄ gas and H₂ gas as the main raw materials, and under conditions including a reduced pressure atmosphere of not more than 3,000 Pa, a substrate temperature of approximately 200° C. and a plasma generation frequency of not less than 40 MHz and not more than 100 MHz, a crystalline silicon p-layer 41, a crystalline silicon i-layer 42 and a crystalline silicon n-layer 43 are deposited, in that order, as the second cell layer 92 on top of the second amorphous silicon layer 7, with the p-layer closest to the surface from which incident sunlight enters. The crystalline silicon p-layer 41 comprises mainly B-doped microcrystalline silicon, and has a thickness of not less than 10 nm and not more than 50 nm. The crystalline silicon i-layer 42 comprises mainly microcrystalline silicon, and has a thickness of not less than 1.2 μm and not more than 3.0 μm. The crystalline silicon p-layer 43 comprises mainly P-doped microcrystalline silicon, and has a thickness of not less than 20 nm and not more than 50 nm.

The crystalline silicon n-layer may also be an amorphous silicon n-layer comprising mainly amorphous silicon, or a stacked structure comprising an amorphous silicon n-layer and a crystalline silicon n-layer. The n-layer 43 may be composed mainly of P-doped silicon, with a thickness of not less than 20 nm and not more than 50 nm. In this case, during deposition of the n-layer 43, the hydrogen dilution ratio H₂/SiH₄ is set to a value of at least 0 but not more than 10-fold. The deposition rate for the n-layer is typically not less than 0.2 nm/second, and preferably not less than 0.25 nm/second.

In those cases where the n-layer 43 has a two-layer structure, the first n-layer formed on the crystalline silicon i-layer 42 is deposited under conditions including a hydrogen dilution ratio of at least 0 but not more than 10-fold. During deposition of the first n-layer, deposition may also be performed using an above-mentioned gas containing at least one element among carbon and nitrogen. The second n-layer is deposited using a different hydrogen dilution ratio from that used for the first n-layer. Depositing the second n-layer at a high deposition rate, and under hydrogen dilution ratio conditions that cause deposition of amorphous silicon (for example, a hydrogen dilution ratio of 20-fold) is advantageous, as it improves productivity and is thought to also improve coverage.

During formation of the i-layer film comprising mainly microcrystalline silicon using a plasma-enhanced CVD method, a distance d between the plasma discharge electrode and the surface of the substrate 1 is preferably set to not less than 3 mm and not more than 10 mm. If this distance d is less than 3 mm, then the precision of the various structural components within the film deposition chamber required for processing large substrates means that maintaining the distance d at a constant value becomes difficult, which increases the possibility of the electrode getting too close and making the discharge unstable. If the distance d exceeds 10 mm, then achieving a satisfactory deposition rate (of at least 1 nm/s) becomes difficult, and the uniformity of the plasma also deteriorates, causing a deterioration in the quality of the film due to ion impact.

(5) FIG. 2(e)

The substrate 1 is mounted on an X-Y table, and the second harmonic of a laser diode excited YAG laser (532 nm) is irradiated onto the film surface of the photovoltaic layer 3, as shown by the arrow in the figure. With the pulse oscillation set to not less than 10 kHz and not more than 20 kHz, the laser power is adjusted so as to achieve a suitable process speed, and laser etching is conducted at a point approximately 100 μm to 150 μm to the side of the laser etching line within the transparent electrode layer 2, so as to form a slot 11. The laser may also be irradiated from the side of the substrate 1, and in this case, because the high vapor pressure generated by the energy absorbed by the amorphous silicon-based first cell layer 91 of the photovoltaic layer 3 can be utilized in etching the photovoltaic layer 3, more stable laser etching processing can be performed. The position of the laser etching line is determined with due consideration of positioning tolerances, so as not to overlap with the previously formed etching line.

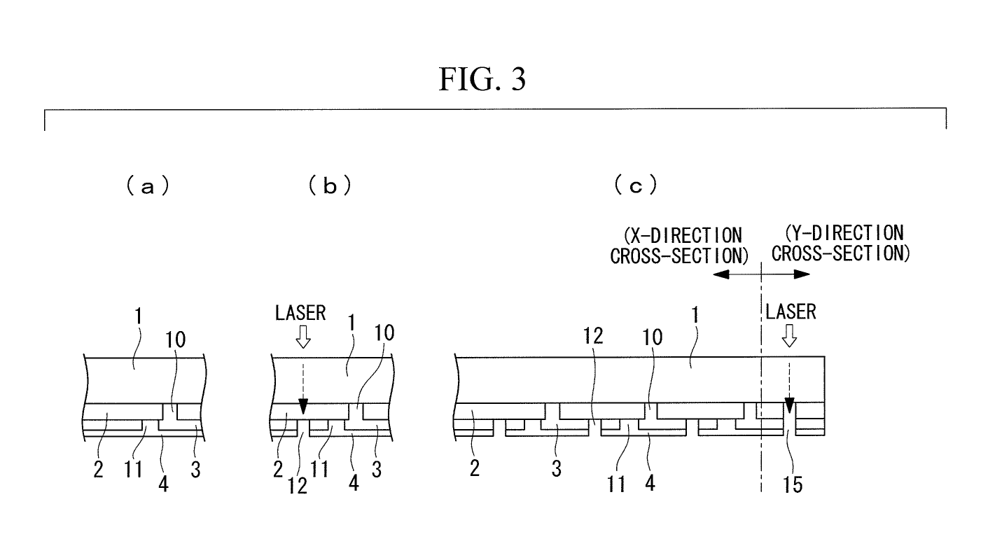

(6) FIG. 3(a)

Using a sputtering apparatus, an Ag film and a Ti film are deposited as the back electrode layer 4, under a reduced pressure atmosphere and at a deposition temperature of 150° C. to 200° C. In this embodiment, an Ag film having a thickness of not less than 150 nm and not more than 500 nm, and a highly corrosion-resistant Ti film having a thickness of not less than 10 nm and not more than 20 nm, which acts as a protective film for the Ag film, are stacked in that order. Alternatively, the back electrode layer 4 may be formed as a stacked structure composed of an Ag film having a thickness of 25 nm to 100 nm, and an Al film having a thickness of 15 nm to 500 nm. In order to reduce the contact resistance between the crystalline silicon n-layer 43 and the back electrode layer 4 and improve the reflectance, a GZO (Ga-doped ZnO) film with a film thickness of not less than 50 nm and not more than 100 nm may be deposited between the photovoltaic layer 3 and the back electrode layer 4 using a sputtering apparatus.

(7) FIG. 3(b)

The substrate 1 is mounted on an X-Y table, and the second harmonic of a laser diode excited YAG laser (532 nm) is irradiated through the substrate 1, as shown by the arrow in the figure. The laser light is absorbed by the photovoltaic layer 3, and by utilizing the high gas vapor pressure generated at this point, the back electrode layer 4 is removed by explosive fracture. With the pulse oscillation set to not less than 1 kHz and not more than 10 kHz, the laser power is adjusted so as to achieve a suitable process speed, and laser etching is conducted at a point approximately 250 μm to 400 μm to the side of the laser etching line within the transparent electrode layer 2, so as to form a slot 12.

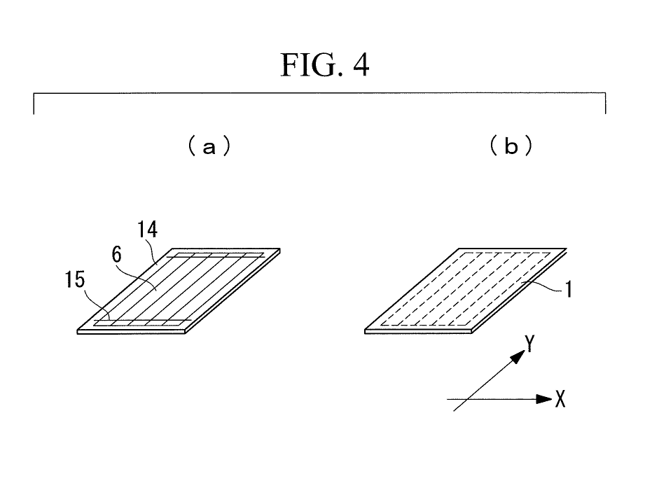

(8) FIG. 3(c) and FIG. 4(a)

The electric power generation region is then compartmentalized, by using laser etching to remove the effect wherein the serially connected portions at the film edges near the edges of the substrate are prone to short circuits. The substrate 1 is mounted on an X-Y table, and the second harmonic of a laser diode excited YAG laser (532 nm) is irradiated through the substrate 1. The laser light is absorbed by the transparent electrode layer 2 and the photovoltaic layer 3, and by utilizing the high gas vapor pressure generated at this point, the back electrode layer 4 is removed by explosive fracture, and the back electrode layer 4, the photovoltaic layer 3 and the transparent electrode layer 2 are removed. With the pulse oscillation set to not less than 1 kHz and not more than 10 kHz, the laser power is adjusted so as to achieve a suitable process speed, and laser etching is conducted at a point approximately 5 mm to 20 mm from the edge of the substrate 1, so as to form an X-direction insulation slot 15 as illustrated in FIG. 3(c). FIG. 3(c) represents an X-direction cross-sectional view cut along the direction of the series connection of the photovoltaic layer 3, and therefore the location in the figure where the insulation slot 15 is formed should actually appear as a peripheral film removed region 14 in which the back electrode layer 4, the photovoltaic layer 3 and the transparent electrode layer 2 have been removed by film polishing (see FIG. 4(a)), but in order to facilitate description of the processing of the edges of the substrate 1, this location in the figure represents a Y-direction cross-sectional view, so that the formed insulation slot represents the X-direction insulation slot 15. A Y-direction insulation slot need not be provided at this point, because a film surface polishing and removal treatment is conducted on the peripheral film removal regions of the substrate 1 in a later step.

Completing the etching of the insulation slot 15 at a position 5 mm to 15 mm from the edge of the substrate 1 is preferred, as it ensures that the insulation slot 15 is effective in inhibiting external moisture from entering the interior of the solar cell module 6 via the edges of the solar cell panel.

Although the laser light used in the steps until this point has been specified as YAG laser light, light from a YVO4 laser or fiber laser or the like may also be used in a similar manner.

(9) FIG. 4 (a: View from Solar Cell Film Surface Side, b: View from Substrate Side of Light Incident Surface)

In order to ensure favorable adhesion and sealing of a backing sheet 24 via EVA or the like in a subsequent step, the stacked films around the periphery of the substrate 1 (in a peripheral film removal region 14), which tend to be uneven and prone to peeling, are removed to form a peripheral film removed region 14. During removal of the films from a region that is 5 mm to 20 mm from the edge around the entire periphery of the substrate 1, grinding or blast polishing or the like is used to remove the back electrode layer 4, the photovoltaic layer 3 and the transparent electrode layer 2 from a region that is closer to the substrate edge in the X direction than the insulation slot 15 provided in the above step of FIG. 3(c), and closer to the substrate edge in the Y direction than the slot 10 provided near the substrate edge.

Grinding debris or abrasive grains are removed by washing the substrate 1.

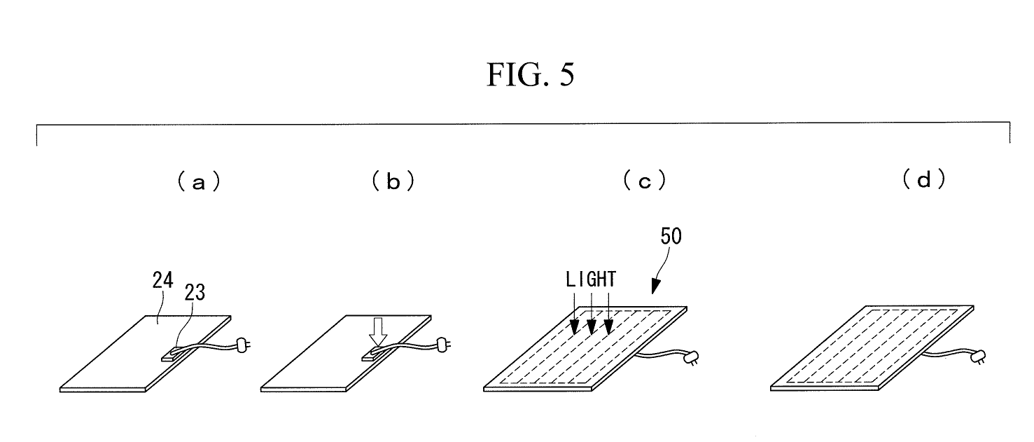

(10) FIG. 5(a) (b)

An attachment portion for a terminal box 23 is prepared by providing an open through-window in the backing sheet 24 to expose a collecting plate. A plurality of layers of an insulating material are provided in this open through-window portion in order to prevent external moisture and the like entering the solar cell module.

Processing is conducted so as to enable current collection, using a copper foil, from the series-connected solar cell electric power generation cell at one end, and the solar cell electric power generation cell at the other end, in order to enable electric power to be extracted from the terminal box 23 on the back surface of the solar cell panel. In order to prevent short circuits between the copper foil and the various portions, an insulating sheet that is wider than the width of the copper foil is provided.

Following arrangement of the collecting copper foil and the like at predetermined positions, the entire solar cell module 6 is covered with a sheet of an adhesive filling material such as EVA (ethylene-vinyl acetate copolymer), which is arranged so as not to protrude beyond the substrate 1.

A backing sheet 24 with a superior waterproofing effect is then positioned on top of the EVA. In this embodiment, in order to achieve a superior waterproofing and moisture-proofing effect, the backing sheet 24 is formed as a three-layer structure comprising a PET sheet, an Al foil and another PET sheet.

The structure comprising the components up to and including the backing sheet 24 arranged in predetermined positions is subjected to internal degassing under a reduced pressure atmosphere and under pressing at approximately 150° C. to 160° C. using a laminator, thereby causing cross-linking of the EVA that tightly seals the structure.

(11) FIG. 5(a)

The terminal box 23 is attached to the back of the solar cell module 6 using an adhesive.

(12) FIG. 5(b)

The copper foil and an output cable from the terminal box 23 are connected using solder or the like, and the interior of the terminal box 23 is filled and sealed with a sealant (a potting material). This completes the production of the solar cell panel 50.

(13) FIG. 5(c)

The solar cell panel 50 formed via the steps up to and including FIG. 5(b) is then subjected to an electric power generation test, as well as other tests for evaluating specific performance factors. The electric power generation test is conducted using a solar simulator that emits a standard sunlight of AM 1.5 (1,000 W/m²).

(14) FIG. 5(d)

In tandem with the electric power generation test (FIG. 5(c)), a variety of specific performance factors including the external appearance are evaluated.

### EXAMPLES {0040}

### Example 1

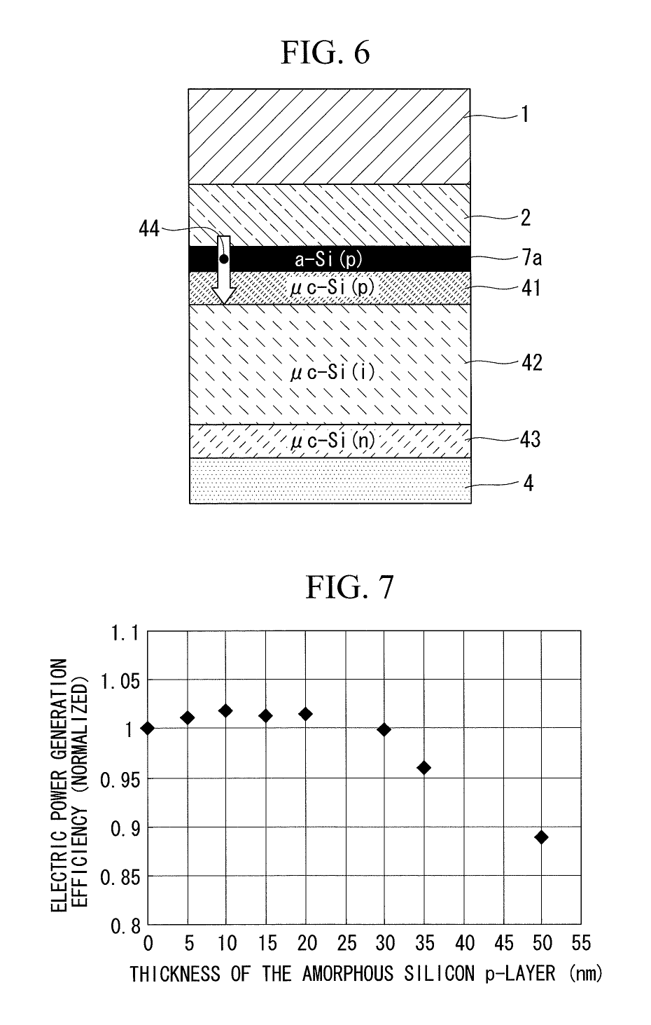

A single crystalline silicon solar cell was prepared with the type of structure illustrated in FIG. 6. Using a plasma-enhanced CVD apparatus, a transparent electrode layer (including a plasma-resistant protective layer) 2, a second amorphous silicon p-layer (a-Si(p)) 7a, a crystalline silicon p-layer (μc-Si(p)) 41, a crystalline silicon i-layer (μc-Si(i)) 42, a crystalline silicon n-layer (μc-Si(n)) 43 and a back electrode layer 4 were deposited sequentially on a glass substrate (42 cm×57 cm× thickness: 4 mm) 1.

A tin oxide film having a thickness of 800 nm and a GZO film (plasma-resistant protective layer) having a thickness of 300 nm were formed as the transparent electrode layer 2. A GZO film having a thickness of 80 nm and an Ag film having a thickness of 300 nm were formed as the back electrode layer 4.

For the second amorphous silicon p-layer 7a, a B-doped amorphous silicon film was deposited using H₂, SiH₄ and B₂H₆ as raw material gases, under conditions including a hydrogen dilution ratio of 40-fold, a pressure of 40 Pa, a heater temperature of 180° C., a plasma generation frequency of 13.56 MHz, and a supplied electric power level of 50 W. By altering the deposition time, amorphous silicon p-layers of various thicknesses were formed.

For the crystalline silicon p-layer 41, a B-doped microcrystalline silicon film with a thickness of 20 nm was deposited using H₂, SiH₄ and B₂H₆ as raw material gases, under conditions including a hydrogen dilution ratio of 167-fold, a pressure of 532 Pa, a heater temperature of 190° C., a plasma generation frequency of 60 MHz, and a supplied electric power level of 1,000 W.

For the crystalline silicon i-layer 42, a microcrystalline silicon film with a thickness of 2,000 nm was deposited using H₂ and SiH₄ as raw material gases, under conditions including a hydrogen dilution ratio of 41-fold, a pressure of 798 Pa, a heater temperature of 185° C., a plasma generation frequency of 60 MHz, and a supplied electric power level of 2,440 W.

For the crystalline silicon n-layer 43, a P-doped microcrystalline silicon film with a thickness of 35 nm was deposited using H₂, SiH₄ and PH₃ as raw material gases, under conditions including a hydrogen dilution ratio of 45-fold, a pressure of 80 Pa, a heater temperature of 206° C., a plasma generation frequency of 60 MHz, and a supplied electric power level of 500 W.

FIG. 7 illustrates the relationship between the thickness of the second amorphous silicon p-layer 7a and the electric power generation efficiency when the second amorphous silicon p-layer 7a was inserted between the transparent electrode layer 2 and the crystalline silicon p-layer 41. In the figure, the horizontal axis represents the thickness of the second amorphous silicon p-layer 7a, and the vertical axis represents the electric power generation efficiency (normalized against a standard value of 1 when the thickness of the second amorphous silicon p-layer 7a is 0 nm). Compared with the case where the second amorphous silicon p-layer 7a was not inserted, insertion of a second amorphous silicon p-layer 7a having a thickness exceeding 30 nm caused a deterioration in the electric power generation efficiency. In contrast, when a second amorphous silicon p-layer 7a having a thickness of 30 nm or less was inserted, the electric power generation efficiency was either maintained or improved, and when the thickness was not less than 5 nm and not more than 20 nm, the electric power generation efficiency improved by approximately 2%. It is thought that the above results are due to an effect wherein by inserting a second amorphous silicon p-layer 7a of a prescribed thickness between the transparent electrode layer 2 and the crystalline silicon p-layer 41, diffusion of oxygen 44 contained within the transparent electrode layer 2 into the crystalline silicon p-layer 41 can be prevented.

### Example 2

A second amorphous silicon i-layer comprising mainly amorphous silicon was deposited instead of the second amorphous silicon p-layer 7a within a single crystalline silicon solar cell having the type of structure illustrated in FIG. 6. The steps other than the deposition step for the second amorphous silicon i-layer were performed in the same manner as Example 1, thus preparing a single crystalline silicon solar cell.

For the second amorphous silicon i-layer, an amorphous silicon film was deposited using H₂ and SiH₄ as raw material gases, under conditions including a hydrogen dilution ratio of 6-fold, a pressure of 60 Pa, a heater temperature of 237° C., a plasma generation frequency of 60 MHz, and a supplied electric power level of 150 W. By altering the deposition time, i-layers of various thicknesses were formed.

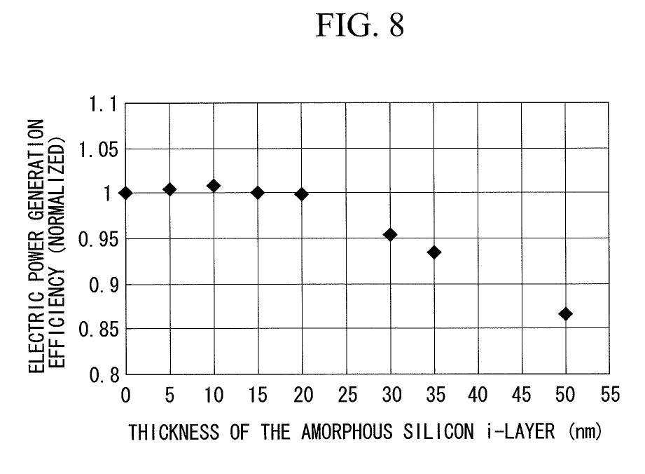

FIG. 8 illustrates the relationship between the thickness of the second amorphous silicon i-layer and the electric power generation efficiency when the second amorphous silicon i-layer was inserted between the transparent electrode layer and the crystalline silicon p-layer. In the figure, the horizontal axis represents the thickness of the second amorphous silicon i-layer, and the vertical axis represents the electric power generation efficiency (normalized against a standard value of 1 when the thickness of the second amorphous silicon i-layer is 0 nm). Compared with the case where the second amorphous silicon i-layer was not inserted, insertion of a second amorphous silicon i-layer having a thickness exceeding 20 nm caused a deterioration in the electric power generation efficiency. In contrast, when a second amorphous silicon i-layer having a thickness of 20 nm or less was inserted, the electric power generation efficiency was either maintained or improved, and when the thickness was not less than 5 nm and not more than 10 nm, the electric power generation efficiency improved by approximately 1%.

The above results confirmed that regardless of whether the second amorphous silicon layer inserted between the transparent electrode layer and the crystalline silicon p-layer was a p-layer or an i-layer, the electric power generation efficiency could be either maintained or improved. Further, the p-layer produced a greater improvement in the electric power generation efficiency than the i-layer. It is thought that this observation is due to the fact that the p-layer has lower electrical resistance than the i-layer, resulting in a reduced contact resistance at the interface between the transparent electrode layer and the crystalline silicon layer.

In the embodiment described above, single solar cells and tandem solar cells were described as the solar cell, but the present invention is not limited to these particular examples, and may also be applied in a similar manner to other types of thin-film solar cells such as silicon-germanium solar cells and triple solar cells.

### REFERENCE SIGNS LIST

1 Substrate
2 Transparent electrode layer
3 Photovoltaic layer
4 Back electrode layer
5 Intermediate contact layer
6 Solar cell module
7 Second amorphous silicon layer
10, 12 Slot
11 Connection slot
14 Peripheral film removal region
15 Insulation slot
23 Terminal box
24 Backing sheet
31 First amorphous silicon p-layer
32 First amorphous silicon i-layer
33 First amorphous silicon n-layer
41 Crystalline silicon p-layer
42 Crystalline silicon i-layer
43 Crystalline silicon n-layer
44 Oxygen
50 Solar cell panel
91 First cell layer
92 Second cell layer
100 Photovoltaic device (tandem)

1. A photovoltaic device comprising a transparent electrode layer and one or more photovoltaic layers stacked on a substrate, wherein
at least one of the photovoltaic layers comprises a p-type crystalline silicon layer, an i-type crystalline silicon layer and an n-type silicon layer, and
an amorphous silicon layer is disposed between and adjacent to the transparent electrode layer and the p-type crystalline silicon layer.

2. The photovoltaic device according to claim 1, wherein
the photovoltaic device comprises two or more of the photovoltaic layers,
the transparent electrode layer is an intermediate contact layer disposed between a pair of the two or more photovoltaic layers,
among the pair of photovoltaic layers, a photovoltaic layer positioned on an opposite side of the intermediate contact layer from the substrate comprises a p-type crystalline silicon layer containing mainly crystalline silicon, an i-type crystalline silicon layer and an n-type silicon layer, and
an amorphous silicon layer is disposed between and adjacent to the intermediate contact layer and the p-type crystalline silicon layer.

3. The photovoltaic device according to claim 1, wherein the amorphous silicon layer is a p-type amorphous silicon layer or an i-type amorphous silicon layer.

4. The photovoltaic device according to claim 2, wherein the amorphous silicon layer is a p-type amorphous silicon layer or an i-type amorphous silicon layer.

5. The photovoltaic device according to claim 1, wherein a thickness of the amorphous silicon layer is not less than 1 nm and not more than 30 nm.

6. The photovoltaic device according to claim 2, wherein a thickness of the amorphous silicon layer is not less than 1 nm and not more than 30 nm.

7. The photovoltaic device according to claim 3, wherein a thickness of the amorphous silicon layer is not less than 1 nm and not more than 30 nm.

8. The photovoltaic device according to claim 4, wherein a thickness of the amorphous silicon layer is not less than 1 nm and not more than 30 nm.
